(19) United States
(12) Patent Application Publication
(10) Pub. No.: US 2006/0125061 A1
(43) Pub. Date: Jun. 15, 2006

(54) Board or substrate for an organic electronic device and use thereof

(76) Inventors: Wolfgang Clemens, Puschendorf (DE); Axel Gerlt, Furth (DE)

Correspondence Address: CARELLA, BYRNE, BAIN, GILFILLAN, CECCHI,;STEWART & OLSTEIN, 5 BECKER FARM ROAD, ROSELAND, NJ, 07068, US

(21) Appl. No.: 10/541,956

(22) PCT Filed: Dec. 16, 2003
(86) PCT No.: PCT/DE03/04151

§ 371 Date: Oct. 31, 2005

(30) Foreign Application Priority Data
Jan. 9, 2003 (DE) 103 00 519.6

(51) Int. Cl. H01L 23/495

(52) U.S. Cl. 257/666

(57) ABSTRACT

The invention relates to a circuit board or a substrate for an electronic device, which is inexpensive to produce and easy to integrate in the production process for organic electronics. To this end, the novel intelligent circuit board comprises at least one active electronic component, for example an electrical circuit, which is integrated in the circuit board.

The invention relates to a circuit board or a substrate for an electronic device, which is inexpensive to produce and easy to integrate in the production process for organic electronics.

Electronic components which are applied on so-called circuit boards are known. Individual active electronic elements such as transistors, integrated circuits etc. are in this case soldered onto passive circuit boards and conductively connected either by pre-structured conductive tracks on the circuit board or by cable lines. The individual active electronic components are all fabricated separately and mounted on the circuit board in an additional working step (hybrid structure). To date, it is only possible to integrate passive components such as resistors or capacitors in such circuit boards, all the active parts being constructed as described in a hybrid fashion.

In organic electronics, so-called polymer electronics, it is known to construct organically based (not necessarily only using polymers, but in general terms using conductive, semiconducting and insulating organic materials, i.e. materials not containing silicon) active components such as transistors, or passive components such as resistors, on substrates, and preferably flexible substrates.

In order to produce so-called organic electronics, electronics which are constructed not using traditional semiconductors with silicon as a key element, but which comprise organic semiconducting and conducting materials, it is necessary to provide electronics which are as inexpensive as possible.

It is therefore an object of the present invention to provide a circuit board, a substrate or a base plate (all three terms refer here to the same equipment) for an organic device which is intelligent or in which passive and/or active electronic components are integrated.

The invention relates to a circuit board or substrate for an electronic device, in which active components such as transistors, diodes, photocells, integrated circuits or the like and/or passive components such as a resistors, coils and/or capacitors are integrated.

Here, the term “integrated” is used in contrast to the aforementioned hybrid structure. The integrated components are therefore not fabricated separately and/or mounted on the substrate in an additional working step, but instead the substrate is used according to the invention both as a (conventional) circuit board and for constructing the integrated electronics (hence “intelligent circuit board”). Here, the term “integrated” naturally also includes, for example, being applied on the surface, e.g. printed.

For an electronic device such as a sensor label, a game, a check card or an RFID tag, it is important that a plurality of electronically different components or parts should be electrically connected over a sizeable area. Since the (production) costs play a crucial role in organic electronics, it is important to provide an opportunity for inexpensive electronics, with the aid of which entire electronic devices can be integrated in a substrate and therefore produced in one process.

The entire electronic device is preferably produced in a so-called thin film process (thin organic functional layers which are inexpensive and easy to produce) and/or in a printing process, in particular preferably at least partially in the roll-to-roll process. Low costs and high production runs can be achieved in this way.

The (entire) power supply for the electronic device, such as an energy transducer, a photovoltaic cell, a piezoceramic element, a coil for inductive coupling, an antenna for capacitive coupling, a contact to an external power supply, a battery or the like can be integrated on a substrate or in an intelligent circuit board according to the invention. An input element, i.e. a sensor, or a keypad, as well as an output element, an antenna or the like, can furthermore be integrated in the substrate or on the intelligent circuit board. The following components will be referred to here by way of example as an input element: sensor (for pressure, electrical current, electrical voltage, noise, temperature, humidity, pH, chemical compounds, gases, alcohol in breath and/or blood, analysis of bodily fluids or aqueous starting materials in general), keypad (individual push buttons (simple connections or capacitively coupled buttons or inductive buttons), keyboard, input matrix (for example touch screen)), microphone (sound, noise), light sensor (also as a detector or solar cell).

The following components will be referred to here by way of example as output elements: optical elements (light-emitting diodes (organic or inorganic), incandescent lamps, electrochromic elements (ones which change their color or light absorption under the effect of electrical current/electrical voltage, liquid crystal displays (LCDs); loudspeakers (conventional or based on (organic or inorganic) piezo-active materials), antennas (inductive as a coil or capacitive), electrical contacts for external contacting, screen (based on all possible principles such as conventional picture tube screens, LCD (liquid crystal) displays, screens based on electrochromic materials, on so-called E-ink (name of an American company).

Conventional wired or cable connections can be simply replaced, for example by structured electrically conducting layers and/or conductive tracks producible by printing techniques.

According to one embodiment, the substrate on which the active elements, for example individual transistors or integrated circuits, are constructed is simultaneously used as a circuit board and the conductive connections (or resistors, coils or antennas) necessary for this are also applied directly on the same substrate. For example, the source/drain or gate electrode planes of the integrated circuits may be used over a large area for these conductive tracks. It is therefore also possible to include hybrid constructs as well, for example to apply a battery, a button or sensor and/or a silicon chip at points on the intelligent circuit board or the substrate. Conductive tracks or conducting contacts may, for example, also be produced using conductive adhesives.

The substrate may be a flexible film, although it may also be made of any other suitable material, and almost any desired material.

It is also possible for an inexpensive display, which is based on the electrochromic effect, to be integrated on an intelligent circuit board or a substrate according to the invention, for example with an electrochromic material being used as the display element and organic transistors being used as the driver circuit. This is particularly beneficial economically since displays have previously been used almost exclusively for highly priced products.

The display may either be plugged on or integrated in a different way, although it may also be regarded as an independent component. The connections may, for example, be produced using a conductive adhesive. Contactless transmission of data from an external device to the display is also possible (for example using a coil).

There may also be other functions, for example the sensor properties for temperature, humidity or further logic functions, preferably but not necessarily organic based components. A volatile or nonvolatile memory may likewise be integrated (organic or inorganic based).

In the electrochromic effect, the color of a material is changed reversibly or irreversibly by applying an electrical voltage. For example, the color can be changed from almost clear to dark blue in the material PEDOT/PSS, and from green to blue in PANI. This is implemented by a structure in which a second electrode is placed next to or above the electrochromic material, and these two elements are connected by an electrolyte. When a voltage is applied between the two elements, a redox reaction takes place in the electrochromic material and finally leads to the color change. Generally, a significant change in the electrical resistance of the materials also takes place during this reaction.

Driving is required for such a display, if it is not just a simple symbol but a variable display, for example as in the case of a 7 segment display or a matrix display. This driving must deliver the incoming signals to the display so that they are correlated, for example using NOR logic, in order for the intended display to light up. This driving is preferably constructed as an organic circuit based on organic field-effect transistors, the function and structure of which are known.

The display and the driver electronics may, for example, be integrated on the same substrate in the same production step. The substrate is typically an inexpensive polymer film (for example PET, or PP, or PEN. or polyimide). The display principle may be implemented very simply and inexpensively (for example according to the publication by the Swedish Institute ACREO). This construction, too, may be carried out in the thin film process and implemented by printing processes. For the first time, therefore, it is possible to achieve both low costs and high production runs for displays.

The invention will be explained in more detail below with reference to practical examples which represent embodiments:

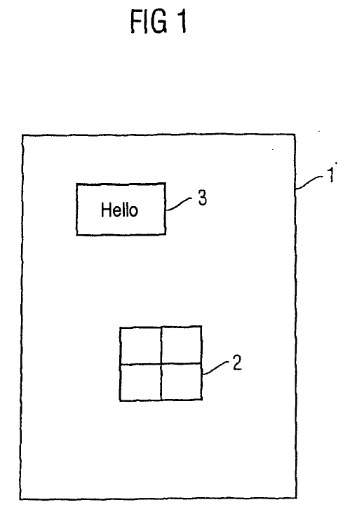

FIG. 1 shows the plan view of an electronic organic device, which comprises at least one organic component,

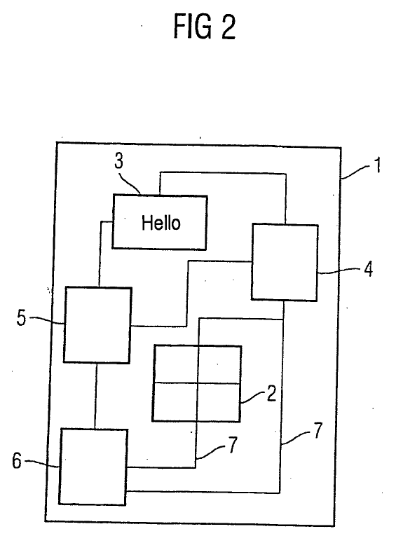

FIG. 2 shows the plan view of the same electronic device, but showing the layer located under the package,

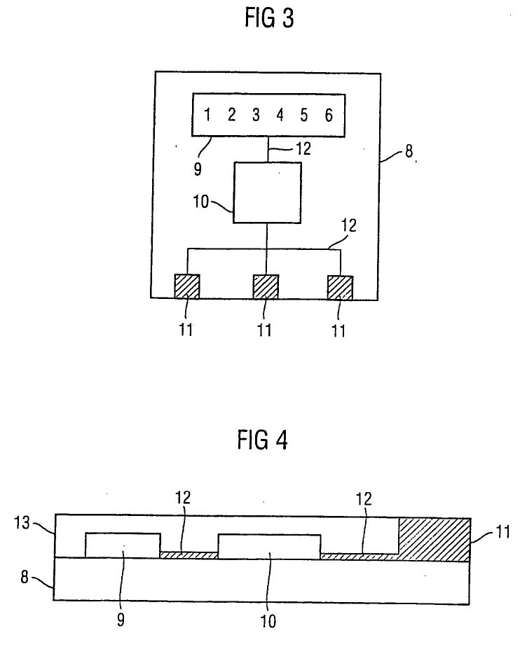

FIG. 3 shows the plan view of a 7 segment IPC display, and

FIG. 4 shows the cross section through an IPC display.

FIG. 1 shows the surface of the intelligent circuit board or the substrate surface 1, in which case the substrate may for example be a flexible film, cardboard, a flexible or conventional glass substrate or the like. Externally visible are the input elements (keypad, sensors, etc.) and the output elements 3 (display, visualization, luminous element, loudspeakers). The inner workings of the electronic device are covered by an opaque cover surface. The cover surface may be configured or printed in any desired way. Each of the aforementioned or usable electronic components may be organic, although it is also possible to combine organic and conventional, silicon based components in any desired way.

FIG. 2 shows the structure of the intelligent circuit board or the substrate according to the invention, with the layer below the opaque cover surface (“the inner workings”) in FIG. 1 being shown. Here, it can be seen that there are also further elements 4, 5, 6 and electrical connections 7 between them on the substrate 1, in addition to the visible input and output elements 2, 3. These elements 4 to 7 may either be electronic elements applied directly on the substrate 1 (integrated circuit, sensors, memory) or elements applied as hybrids, such as a batteries, loudspeakers, conventional electronics, memories etc. According to the invention, both the conducting connections and the active electronic elements can be applied on the substrate. The invention may therefore also be used, for example, for the inexpensive production of greetings cards with small electronic games. In conventional greetings cards which play a short tune or the like when they are opened, the individual components have previously been connected for example by wires. These connections can be made much simpler according to the invention.

FIG. 3 shows the plan view of a 7 segment IPC display. An electrochromic display 9 and driver electronics 10 necessary for this, which are based on organic transistors, are applied on a flexible substrate 8. Contacts 11 are provided for contacting the display, and the electrical connection between the driver electronics 10 and the display 9 is produced using electrical connections 12.

Lastly, FIG. 4 also shows a cross section through the IPC display. Besides the elements already described in FIG. 3, the protective layer 13 which protects the system from external effects can also be seen.

Functional polymers such as PANI, PEDOT or similar materials, for example macromolecules which have been doped with chemical additives, are for example used in the electrochromic display.

The invention makes it possible, for the first time, to co-integrate a circuit board as an active electronic component in an electronic device rather than using it so to speak as a base plate. This provides an electronic device which not only has a substantially flatter and more compact structure, but also an electronic device which can be produced simply and inexpensively as a low-cost disposable product, including the circuit board and, depending on the embodiment, even including the display.

1. A circuit board or substrate for an electronic device, comprising:
a substrate:
at least one active organic electronic component integrated on the substrate; the organic electronic component having at least one electrode layer;
the at least one electrode layer of the integrated active organic electronic component forming a conductive track layer of a base plate for a conventional semiconductor component.

2. A circuit board or substrate for an electronic device comprising:
a substrate; and
at least one active organic component and at least one passive organic component integrated on the substrate.

3. The circuit board or substrate as claimed in claim 2, wherein the at least one active component is one of an organic transistor, an organic diode, an organic photocell, an organic integrated circuit and/or the passive organic component is one of an electrically conducting connection, a resistor, a coil and/or a capacitor.

4. The circuit board or substrate as claimed in one of the preceding claims, including a power supply integrated on the substrate.

5. The circuit board or substrate as claimed in any of claims 1 to 3 wherein an input element and/or an output element is integrated on the substrate.

6. The circuit board or substrate as claimed in any of claims 1 to 3 wherein electrically conductive lines or conducting contacts are produced using structured conductive layers, electrodes such as source and drain electrodes and/or conductive adhesives.

7. The circuit board or substrate as claimed in any of claims 1 to 3 wherein, an inexpensive visualization element and/or a display is integrated on the substrate.

8. The circuit board or substrate as claimed in claim 7 wherein the display comprises electrochromic material, liquid crystalline elements and/or organic light-emitting diodes.

9. The circuit board or substrate as claimed in claim 7 wherein a driver circuit associated with the display is integrated on the substrate.

10. The circuit board or substrate of claim 7 wherein a driver electronics is included and comprises at least one organic field-effect transistor.

11. The use of the circuit board or substrate as claimed in one of claims 1 to 3 for an electronic device including any of a sensor label, an advertising ticket, a price marker, a game, a check card and an RFID tag.

12. The circuit board or substrate as claimed in claim 8 wherein a driver circuit associated with the display is integrated on the substrate.

13. The circuit board or substrate of claim 8 wherein a driver electronics is included and comprises at least one organic field-effect transistor.

14. The circuit board or substrate of claim 9 wherein a driver electronics is included and comprises at least one organic field-effect transistor.

15. The use of the circuit board or substrate as claimed in claim 4 for an electronic device including any of a sensor label, an advertising ticket, a price marker, a game, a check card and an RFID tag.

16. The use of the circuit board or substrate as claimed in claim 5 for an electronic device including any of a sensor label, an advertising ticket, a price marker, a game, a check card and an RFID tag.

17. The use of the circuit board or substrate as claimed in claim 6 for an electronic device including any of a sensor label, an advertising ticket, a price marker, a game, a check card and an RFID tag.

18. The use of the circuit board or substrate as claimed in claim 7 for an electronic device including any of a sensor label, an advertising ticket, a price marker, a game, a check card and an RFID tag.

19. The use of the circuit board or substrate as claimed in claim 8 for an electronic device including any of a sensor label, an advertising ticket, a price marker, a game, a check card and an RFID tag.

20. The use of the circuit board or substrate as claimed in claim 9 for an electronic device including any of a sensor label, an advertising ticket, a price marker, a game, a check card and an RFID tag.

21. The use of the circuit board or substrate as claimed in claim 10 for an electronic device including any of a sensor label, an advertising ticket, a price marker, a game, a check card and an RFID tag.
